(19) United States
(12) Patent Application Publication
(10) Pub. No.: US 2005/0136575 A1
(43) Pub. Date: Jun. 23, 2005

(54) Method for forming gate of semiconductor device

(76) Inventors: Su Ho Kim, Kyoungki-do (KR); Sang Ho Woo, Kyoungki-do (KR); Yong Seok Eun, Kyoungki-do (KR)

Correspondence Address: LADAS & PARRY LLP, 224 SOUTH MICHIGAN AVENUE, SUITE 1200, CHICAGO, IL, 60604, US

(21) Appl. No.: 10/889,483

(22) Filed: Jul. 12, 2004

(30) Foreign Application Priority Data
Dec. 19, 2003 (KR) 2003-94080

(51) Int. Cl. H01L 21/00; H01L 21/84; H01L 21/8242

(52) U.S. Cl. 438/151

(57) ABSTRACT

Disclosed is a method for forming a gate of a semiconductor device. The method includes the steps of forming a first oxide layer on a substrate divided into a cell area and a peripheral circuit area, forming a photoresist film pattern on a cell area, thereby exposing a surface of the first oxide layer, removing the exposed first oxide layer formed in the peripheral circuit area, and then, removing the photoresist film, forming a second oxide layer on a surface of the silicon substrate, in which the first oxide layer of the peripheral circuit area is removed, and on a first gate oxide layer of the cell area, forming a poly silicon layer on the second oxide layer, forming a tungsten silicide layer on the poly silicon layer, and sequentially patterning the tungsten silicide layer, the poly silicon layer, the second oxide layer, and the first oxide layer.

### BACKGROUND OF THE INVENTION

1. Field of the Invention

The present invention relates to a method for forming a gate of a semiconductor device, and more particularly to a method for forming a gate of a semiconductor device capable of improving a leakage current characteristic and a breakdown voltage characteristic by allowing a silicon oxide layer to have sufficient thickness when a dielectric film is formed by using the silicon oxide layer in a semiconductor device, thereby improving reliability of the silicon oxide layer.

2. Description of the Prior Art

Generally, when forming a gate of a semiconductor device, as the integration degree of the semiconductor device is increased, a thickness of a gate oxide layer is reduced in order to increase current. In order to reduce the thickness of the gate oxide layer, a dual gate oxide layer is mainly adopted.

According to the dual gate oxide layer, a cell area is formed with a thick oxide layer, and a peripheral circuit area requiring a high speed is formed with a thin oxide layer, thereby achieving a high speed device.

In a dual gate device, a gate electrode is formed through a tungsten silicide process such that WSi (tungsten silicide) is formed on an upper portion of poly silicon.

However, WSix including SiH₄ radical is mainly used in the tungsten silicide process. Thus, when WSix including an SiH₄ radical is used, a great amount of fluorine component is contained in a film due to a process temperature and source gas. Such fluorine penetrates between lower gate poly silicon and a gate oxide layer through a following annealing process. Accordingly, fluorine penetrating between lower gate poly silicon and a gate oxide layer acts as a Si—F oxide layer. As a result, even though a thickness of the electrical oxide layer of the device is increased, characteristics of the oxide layer, such as breakdown voltage and leakage current, are deteriorated.

### SUMMARY OF THE INVENTION

Accordingly, the present invention has been made to solve the above-mentioned problems occurring in the prior art, and an object of the present invention is to provide a method for forming a gate of a semiconductor device capable of improving a leakage current characteristic and a breakdown voltage characteristic by allowing a silicon oxide layer to have sufficient thickness when a dielectric film is formed by using the silicon oxide layer in a semiconductor device, thereby improving reliability of the silicon oxide layer.

In order to accomplish this object, there is provided a method for forming a gate of a semiconductor device, the method comprising the steps of: forming a first oxide layer on a silicon substrate divided into a cell area and a peripheral circuit area; forming a photoresist film pattern on a cell area, on which a thick oxide layer is formed, thereby exposing a surface of the first oxide layer formed in the peripheral circuit area; removing the exposed first oxide layer formed in the peripheral circuit area, and then, removing the photoresist film; forming a second oxide layer on a surface of the silicon substrate, in which the first oxide layer of the peripheral circuit area is removed, and on a first gate oxide layer of the cell area; forming a poly silicon layer on the second oxide layer; forming a tungsten silicide layer on the poly silicon layer; and sequentially patterning the tungsten silicide layer, the poly silicon layer, the second oxide layer, and the first oxide layer.

### BRIEF DESCRIPTION OF THE DRAWINGS

The above object, features and advantages of the present invention will be more apparent from the following detailed description taken in conjunction with the accompanying drawings, in which:

FIGS. 1a to 1d are sectional views showing a method for forming a gate of a semiconductor device according to one embodiment of the present invention; and

FIGS. 2a and 2b are graphs showing comparison between leakage currents and dielectric breakdown voltages, when conventional MS-WSix and DCS-WSix of the present invention are applied to a semiconductor device achieved through a method for forming a gate of a semiconductor device according to one embodiment of the present invention.

### DETAILED DESCRIPTION OF THE PREFERRED EMBODIMENTS

Hereinafter, a preferred embodiment of the present invention will be described with reference to the accompanying drawings. In the following description and drawings, the same reference numerals are used to designate the same or similar components, and so repetition of the description on the same or similar components will be omitted.

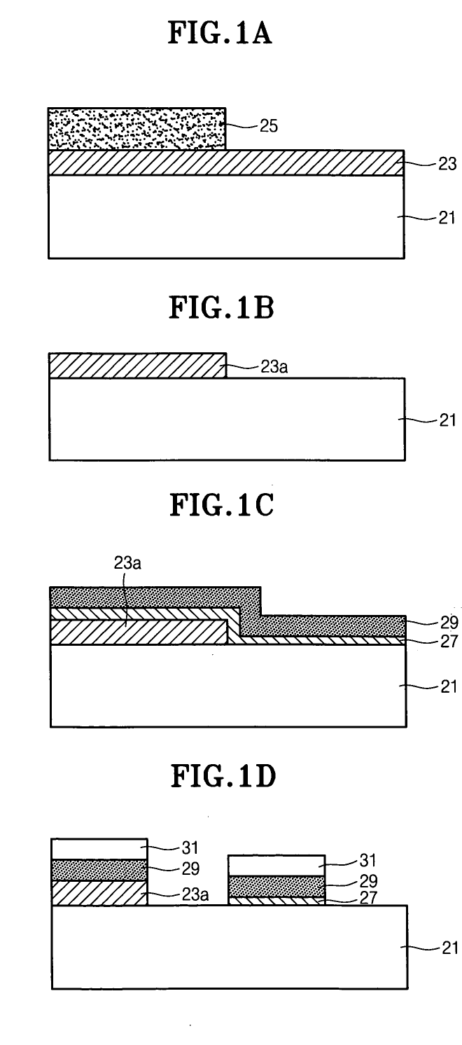

FIGS. 1a to 1d are sectional views showing a method for forming a gate of a semiconductor device according to one embodiment of the present invention.

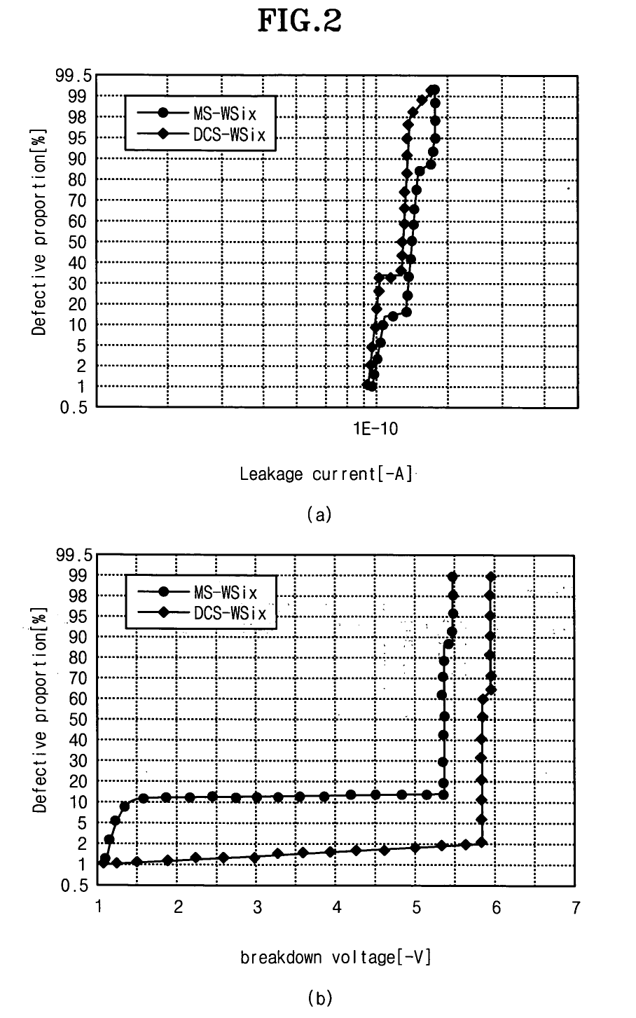

FIGS. 2a and 2b are graphs showing comparison between leakage currents and dielectric breakdown voltages, when conventional MS-WSix and DCS-WSix of the present invention are applied to a semiconductor device achieved through a method for forming a gate of a semiconductor device according to one embodiment of the present invention.

According to a method for forming a gate of a semiconductor device of the present invention, as shown in FIG. 1a, a first gate oxide layer 23 having a predetermined thickness required for the semiconductor device is formed on a silicon substrate 21, in which a predetermined isolation patterning has been performed.

Then, photoresist is coated on an upper portion of the first gate oxide layer 23, which is a cell area, on which a thick oxide layer will be formed. After that, the photoresist is selectively patterned through an exposure and development process of a photolithography technique, thereby forming a photoresist pattern 25. Then, a descum process is carried out in order to prevent photoresist residuals from remaining in a region, on which a thin oxide layer will be formed.

Then, as shown in FIG. 1b, after the descum process has been carried out, an exposed portion of the first gate oxide layer 23 is removed by using predetermined wet-etch solution, that is, chemical solution including HF or BOE, and then, the remaining photoresist pattern 25 is removed.

After that, as shown in FIG. 1c, after the above-mentioned processes have been performed, a second oxide layer 27 is formed on surfaces of the first oxide layer 23 and the silicon substrate 21 by using a wet-oxide process or a dry-oxide process. At this time, a gate oxide layer having a thin thickness is formed at a peripheral region of the silicon substrate, and the first oxide layer is formed with a large thickness.

Thereafter, a polysilicon layer 29 is deposited on the second oxide layer 27 in order to form an electrode.

Then, a cleaning process is carried out by using HF or BOE chemicals in order to remove a natural oxide layer formed on an upper surface of the polysilicon layer 29.

After that, as shown in FIG. 1d, a DCS (dichlorosilaue) (SiH₂Cl₂)-based WSix thin film 31 is formed on the polysilicon layer 29, and a photoresist film pattern (not shown) for a gate electrode is formed on the WSix thin layer 31. Then, the DCS-based WSix thin film 31, the polysilicon layer 29, and the second oxide layer 27 are patterned by using the photoresist pattern as a mask, thereby forming a gate electrode structure. At this time, when the DCS(SiH₂Cl₂)-based WSix thin film 31 is formed, a process temperature is about 400˜700° C., and flow rate of DCS is about 10˜1000 sccm, and flow rate of W source gas is about 1˜100 sccm, and pressure is about 0.1˜10 torr.

According to the present invention, thickness characteristics of an oxide layer can be improved as compared with a conventional MS (SiH₄)-based WSix thin film. In addition, as shown below Table 1, when the in-line thickness of the DCS(SiH₂Cl₂)-based WSix thin film is increased to about 6˜7 Å more than that of the MS (SiH₄)-based WSix thin film, the electrical thickness is increased by about 3 Å. That is, the DCS (SiH₂Cl₂)-based WSix thin layer may increase the in-line (physical) thickness thereof by about 3˜4 Å in order to match with the electrical thickness.

TABLE 1

| Gate Wsix | |
|---|---|
| MS-Wsix | DCS-Wsix |

| Gate use | Thick | Thin | Thick | Thin |
|---|---|---|---|---|
| In-Line gate oxide | 53.4 | 37.4 | 60.0 | 43.1 |
| layer thickness | | | | |
| (Å) | | | | |
| −100 Breakdown | −7.1 | −5.4 | −7.3 | −5.9 |
| Voltage (V) in μA | | | | |
| −3 V, electrical | 63.0 | 47.5 | 66.3 | 51.2 |
| thickness (Å) in | | | | |
| 10 KHZ | | | | |
| Thickness of oxide | 9.6 | 10.1 | 6.3 | 8.1 |
| layer (-In Line | | | | |
| Thk) (Å) | | | | |
| CCST, cum_50% (sec) | 40.9 | 13.1 | 80.3 | 13.3 |

Herein, CCST (constant current stressed time dependant dielectric breakdown) represents resistance with respect to a current stress of an oxide layer.

In addition, as shown in FIG. 2, when DCS (SiH₂Cl₂)-based Wsix is used, a breakdown voltage characteristic and a leakage current characteristic of an oxide layer are improved.

As described above, according to a method for forming a gate of a semiconductor device of the present invention, a DCS (SiH₂Cl₂)-based WSix thin film having a smaller amount of polysilicon and fluorine gas is used as a gate electrode in order to improve characteristics of a semiconductor device. Accordingly, a thickness of a physical oxide layer is increased than that of an MS-base WSix thin film, so the gate breakdown voltage characteristic can be improved.

In addition, device characteristics can be prevented from being deteriorated by current because a thickness of a gate oxide layer is increased.

In addition, the reliability and yield rate of the semiconductor devices can be improved due to improvement of characteristics of such oxide layer.

Although a preferred embodiment of the present invention has been described for illustrative purposes, those skilled in the art will appreciate that various modifications, additions and substitutions are possible, without departing from the scope and spirit of the invention as disclosed in the accompanying claims.

1. A method for forming a gate of a semiconductor device, the method comprising the steps of:
i) forming a first oxide layer on a silicon substrate divided into a cell area and a peripheral circuit area;
ii) forming a photoresist film pattern on a cell area, on which a thick oxide layer is formed, thereby exposing a surface of the first oxide layer formed in the peripheral circuit area;
iii) removing the exposed first oxide layer formed in the peripheral circuit area, and then, removing the photoresist film;
iv) forming a second oxide layer on a surface of the silicon substrate, in which the first oxide layer of the peripheral circuit area is removed, and on a first gate oxide layer of the cell area;
v) forming a poly silicon layer on the second oxide layer;
vi) forming a tungsten silicide layer on the poly silicon layer; and
vii) sequentially patterning the tungsten silicide layer, the poly silicon layer, the second oxide layer, and the first oxide layer.

2. The method as claimed in claim 1, wherein the tungsten silicide layer is a DCS(SiH₂Cl₂)-based WSix thin film.

3. The method as claimed in claim 1, wherein the DCS(SiH₂Cl₂)-based WSix thin film is formed under a process temperature of about 400˜700° C.

4. The method as claimed in claim 1, wherein the DCS(SiH₂Cl₂)-based WSix thin film is formed under a process flow rate of DCS of about 10˜1000 sccm.

5. The method as claimed in claim 1, wherein the DCS(SiH₂Cl₂)-based WSix thin film is formed under a process flow rate of W source gas of about 1˜100 sccm.

6. The method as claimed in claim 1, wherein the DCS(SiH₂Cl₂)-based WSix thin film is formed under a process pressure of about 0.1˜10 torr.

7. The method as claimed in claim 1, further comprising a step of carrying out a descum process after the photoresist film pattern is formed on the first oxide layer.

8. The method as claimed in claim 1, wherein step iii) is carried out by using wet etchant including chemicals having HF or BOE.

9. The method as claimed in claim 1, wherein step iv) is carried out through a wet-oxide process or a dry-oxide process.

10. The method as claimed in claim 1, wherein the second oxide layer formed in the cell area is thicker than the second oxide layer formed in the peripheral circuit area.

11. The method as claimed in claim 1, further comprising a step of carrying out a cleaning process by using HF or BOE chemicals in order to remove contaminants from an upper surface of a poly silicon layer after the poly silicon layer is formed.
